(19) United States
(12) Patent Application Publication
(10) Pub. No.: US 2011/0025442 A1
(43) Pub. Date: Feb. 3, 2011

(54) COMMON MODE FILTER AND METHOD FOR MANUFACTURING THE SAME

(75) Inventors: MING LIANG HSIEH, TAINAN COUNTY (TW); MING YI YANG, YUNLIN COUNTY (TW); LIANG CHIEH WU, TAIPEI COUNTY (TW); SHENG FU SU, KAOHSIUNG COUNTY (TW); CHENG YI WANG, TAIPEI COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: INPAQ TECHNOLOGY CO., LTD., MIAOLI (TW)

(21) Appl. No.: 12/726,691

(22) Filed: Mar. 18, 2010

(30) Foreign Application Priority Data
Aug. 3, 2009 (TW) 098126035

(51) Int. Cl. H01F 5/00

(52) U.S. Cl. 336/200; 29/606

(57) ABSTRACT

A common mode filter comprises an insulating substrate, a lower coil leading layer, a coil main body multilayer, and an upper coil leading layer. The upper coil leading layer comprises at least one upper lead, at least one upper terminal, and at least one upper contact, and the lower coil leading layer comprises at least one lower lead, at least one lower terminal, and at least one lower contact. The two ends of the upper lead are respectively connected to the upper terminal and the upper contact, and the upper lead surrounds the upper contact. The two ends of the lower lead are respectively connected to the lower terminal and the lower contact, and the lower lead surrounds the lower contact. The upper coil leading layer and the lower coil leading layer sandwich the coil main body multi-layer, and the lower coil leading layer is disposed on the insulating substrate.

### BACKGROUND OF THE INVENTION

(A) Field of the Invention

The present invention relates to a common mode filter and a method for manufacturing the same, and more particularly, to a thin-film common-mode filter and a method for manufacturing the same.

(B) Description of the Related Art

A conventional common mode filter serves as a device for suppressing a common mode current which can cause electromagnetic interference between parallel transmission lines. Current applications require the common mode filter to be miniaturized and highly integrated in order to be applied to portable communication apparatuses. Accordingly, thin-film type and multilayer type common-mode filters are gradually replacing conventional coil type common-mode filters. The structure of the coil type common-mode filter is, as its name implies, a coil of wire wrapped around a cylindrical Ferrite core. However, the fabrication of the thin-film type and multilayer type common-mode filters requires more complex semiconductor processes. For example, in the manufacture of the thin-film common-mode filter, a flat coil is formed on a Ferrite plate by a photo lithography technique. In the manufacture of the multilayer type common-mode filter, a metal coil of wire is formed on each of several Ferrite sheets by a screen print technique and a co-firing and pressing process.

In order to adjust the common impedance of a coil circuit, U.S. Pat. No. 7,145,427 introduces a common mode filter. A coil is formed on a magnetic substrate, and notches are formed on the portions of the non-coil structure by etching. Resin with magnetic powders is filled in the notches. The resin-filled surfaces are flattened by a planarization process, and then another magnetic substrate is adhered to the flattened part to finish the filter. This prior art adjusts common impedance by varying the thickness of insulating layers, and hence, the thickness control is a key factor in adjusting the common impedance. However, controlling the thickness of the insulating layers is dependent on processing methods, process parameters and the characteristics of the insulating material. In this regard, it is not easy to control the thickness of the insulating layers in a precise range without incurring high manufacturing costs.

In addition, U.S. Pat. No. 6,356,181 B1 and U.S. Pat. No. 6,618,929 B2 disclose a multilayer type common-mode filter. The pattern of a coil is formed on a magnetic substrate, and a magnetic material is overlaid on the top surface as an upper cover. This prior art particularly changes the route pattern of the coil so as to reduce the impedance of different signals. However, the route pattern of the coil is arranged in continuously different layers, so the forgoing changes are more complicated and there are many variable factors.

In view of above, the consumer electronics market urgently needs a common mode filter which is easy to manufacture and whose common-mode impedance can be precisely adjusted, in order to resolve the aforesaid problems of the conventional common mode filter and reduce the manufacturing cost.

### SUMMARY OF THE INVENTION

One aspect of the present invention is to provide a common mode filter which has a simple structure with adjustable common mode impedance. The leading wires of the common mode filter are wrapped around the contacts in contact holes. Therefore, the common mode impedance can be precisely adjusted by changing the encirclement pattern of the leading wires.

Another aspect of the present invention is to provide a low cost method for manufacturing a common mode filter. The common mode impedance can be adjusted by varying the design of encirclement patterns of the leading wires. Moreover, the pattern can be precisely made by a general photo lithography method so the common mode impedance can be fine tuned. Additionally, the manufacturing cost of the common mode filter does not exceed that of conventional designs.

According to the aforesaid aspect, the present invention provides a common mode filter comprising an insulating substrate, a lower coil leading layer, a coil main body multilayer, and an upper coil leading layer. The upper coil leading layer comprises at least one upper lead, at least one upper terminal, and at least one upper contact, while the lower coil leading layer comprises at least one lower lead, at least one lower terminal, and at least one lower contact. The two ends of the upper lead are respectively connected to the upper terminal and the upper contact, and the upper lead surrounds the upper contact. The two ends of the lower lead are respectively connected to the lower terminal and the lower contact, and the lower lead surrounds the lower contact. The upper coil leading layer and the lower coil leading layer sandwich the coil main body multi-layer, and the lower coil leading layer is disposed on the insulating substrate.

The present invention further provides a method for manufacturing a common mode filter, which comprises the steps of: providing an insulating substrate; forming a lower coil leading layer on the insulating substrate, wherein the lower coil leading layer comprises at least one lower lead, at least one lower terminal, and at least one lower contact, the two ends of the lower lead are respectively connected to the lower terminal and the lower contact, and the lower lead surrounds the lower contact; forming a coil main body multilayer on the lower coil leading layer; and forming an upper coil leading layer on the coil main body multilayer, wherein the upper coil leading layer comprises at least one upper lead, at least one upper terminal, and at least one upper contact, the two ends of the upper lead are respectively connected to the upper terminal and the upper contact, and the upper lead surrounds the upper contact.

With regard to an embodiment of the present invention, a magnetic material layer is further formed on the upper coil leading layer.

### BRIEF DESCRIPTION OF THE DRAWINGS

The objectives and advantages of the present invention will become apparent upon reading the following description and upon reference to the accompanying drawings in which:

FIG. 1 is an exploded schematic diagram of a common mode filter in accordance with an embodiment of the present invention;

FIG. 2 is an exploded schematic diagram of a common mode filter in accordance with another embodiment of the present invention;

FIG. 3A is a schematic diagram of another leading wire 33 in accordance with the present invention;

FIG. 3B is a schematic diagram of another leading wire 33′ in accordance with the present invention;

FIG. 3C is a schematic diagram of a leading wire 33″ in accordance with a prior art;

FIG. 4 is an insertion loss diagram of two leading wires in FIGS. 3A and 3B in comparison with the conventional set of leading wires;

FIG. 5A is a schematic cross-sectional diagram of a common mode filter 50 in accordance with another embodiment of the present invention;

FIG. 5B is a schematic cross-sectional diagram of a common mode filter 50′ in accordance with another embodiment of the present invention; and

FIGS. 6A to 6J illustrate each step of a manufacturing method in accordance with an embodiment of the present invention.

### DETAILED DESCRIPTION OF THE INVENTION

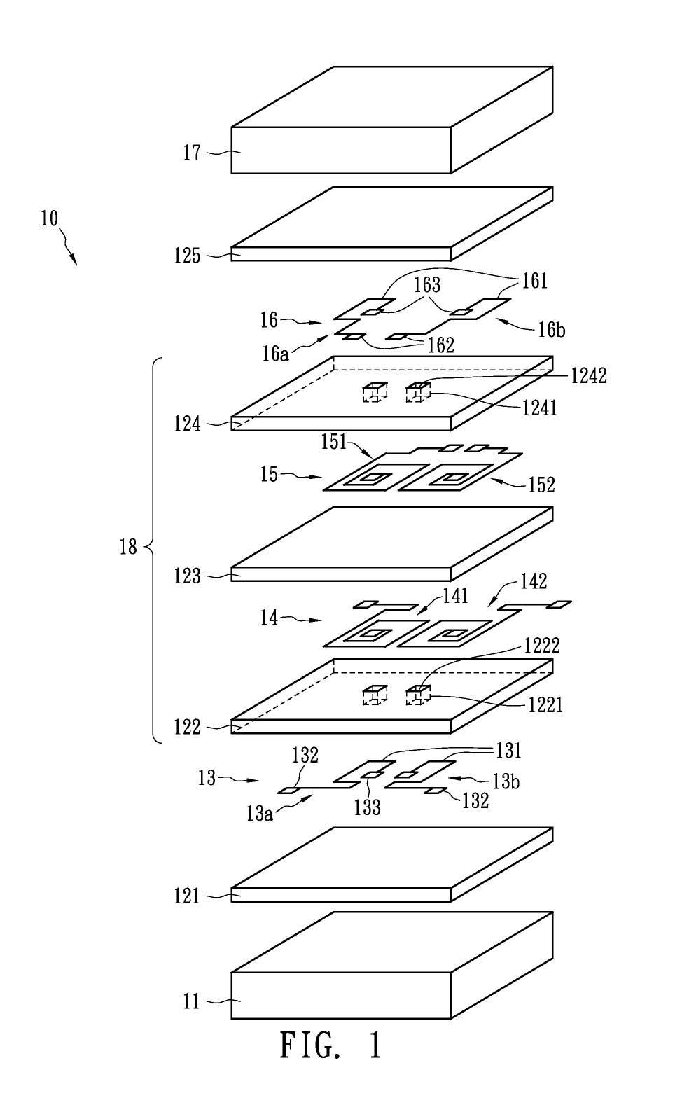

FIG. 1 is an exploded schematic diagram of a common mode filter in accordance with an embodiment of the present invention. As shown in FIG. 1, a common mode filter 10 comprises an insulating substrate 11, a first insulating layer 121, a lower coil leading layer 13, a second insulating layer 122, a first coil main body layer 14, a third insulating layer 123, a second coil main body layer 15, a fourth insulating layer 124, an upper coil leading layer 16, a fifth insulating layer 125 and a magnetic material layer 17. The second insulating layer 122, the first coil main body layer 14, the third insulating layer 123, the second coil main body layer 15, and the fourth insulating layer 124 constitute a coil main body multilayer 18.

The lower coil leading layer 13 further includes two sets of lower coil leading wires 13a and 13b. Each set includes a lower lead 131, a lower terminal 132, and a lower contact 133. The two ends of the lower lead 131 are respectively connected to the lower terminal 132 and the lower contact 133, and the lower lead 131 surrounds the lower contact 133. When a current passes through the lower lead 131, there is an inductance effect because the route of the lower lead 131 is relatively around the lower contact 133. Consequently, the common mode impedance is increased. Similarly, the upper coil leading layer 16 further includes two sets of upper coil leading wires 16a and 16b. Each set includes an upper lead 161, an upper terminal 162, and an upper contact 163, and the upper lead 161 surrounds the upper contact 163.

The first coil main body layer 14 includes two spiral coils 141 and 142. Each of the spiral coils 141 and 142 is electrically connected to one of the sets of lower coil leading wires 13a and 13b through a conductor 1222 filled in one of holes 1221 of the second insulating layer 122. Similarly, the second coil main body layer 15 also includes two spiral coils 151 and 152. Each of the spiral coils 151 and 152 is electrically connected to one of the sets of upper coil leading wires 16a and 16b through a conductor 1242 filled in one of holes 1241 of the fourth insulating layer 124. In this embodiment, there are two set of spiral coils, but the present invention is not limited to such example. That is, additional sets of spiral coils can be formed in a common mode filter.

The material of the insulating substrate 11 can be Al₂O₃, AlN, glass, quartz, or ferrite. The material of the insulating layers 121-125 can be polyimide, epoxy resin, benzocyclobutene (BCB), or polymer. The materials of the lower coil leading layer 13, the first coil main body layer 14, the second coil main body layer 15, and the upper coil leading layer 16 can be Ag, Pd, Al, Cr, Ni, Ti, Au, Cu, or Pt. The magnetic material layer 17 can be a magnetic substrate or adhesive with magnetic powders. Polyimide, epoxy resin, BCB or polymer can be mixed with magnetic powders to obtain the adhesive with magnetic powders.

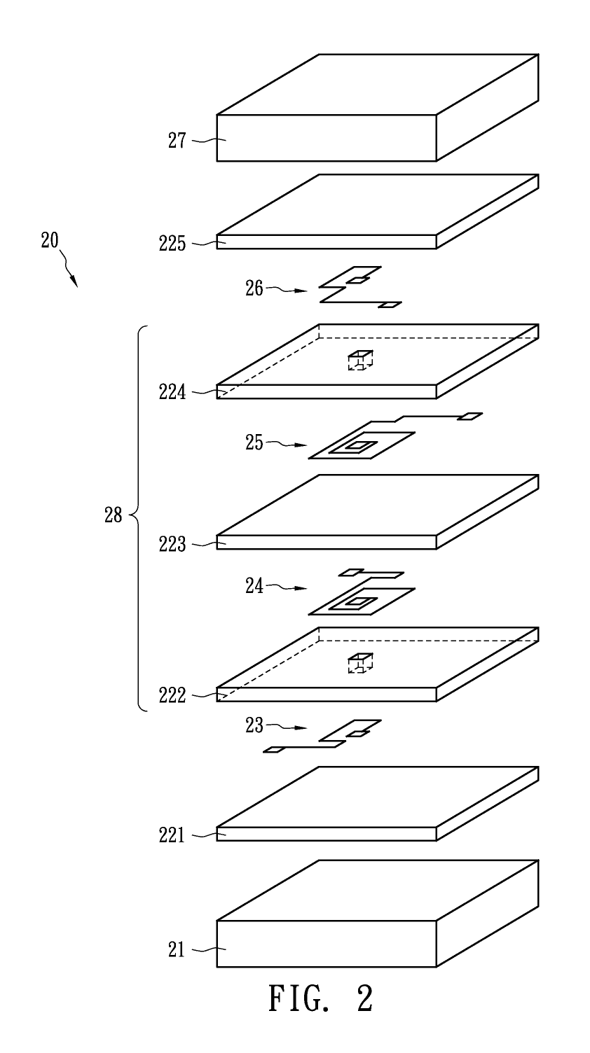

FIG. 2 is an exploded schematic diagram of a common mode filter in accordance with another embodiment of the present invention. As shown in FIG. 2, a common mode filter 20 comprises an insulating substrate 21, a first insulating layer 221, a lower coil leading layer 23, a second insulating layer 222, a first coil main body layer 24, a third insulating layer 223, a second coil main body layer 25, a fourth insulating layer 224, an upper coil leading layer 26, a fifth insulating layer 225 and a magnetic material layer 27. In comparison with the embodiment in FIG. 1, the common mode filter 20 comprises only one set of the spiral coil. The second insulating layer 222, the first coil main body layer 24, the third insulating layer 223, the second coil main body layer 25, and the fourth insulating layer 224 constitute a coil main body multilayer 28.

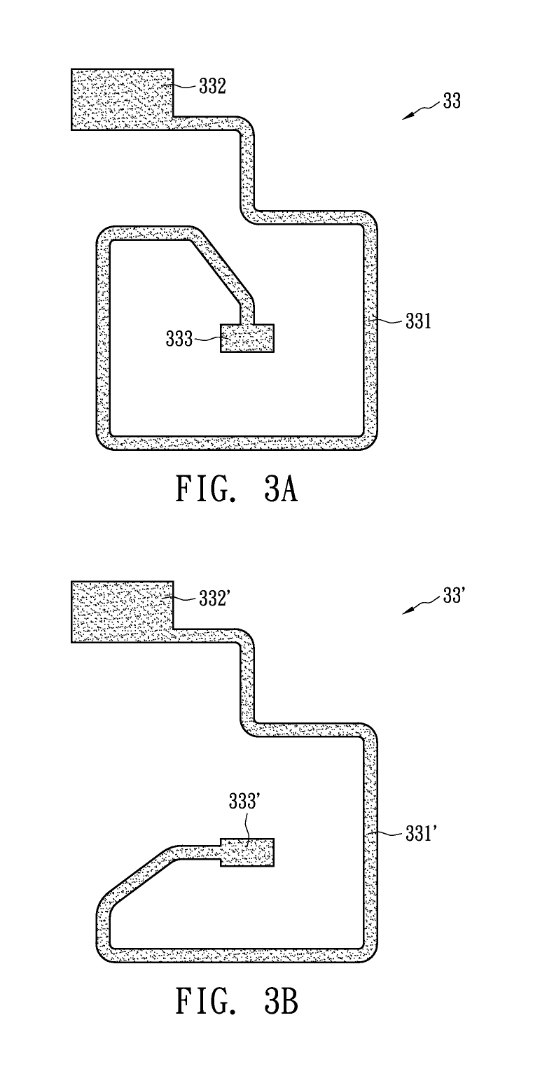

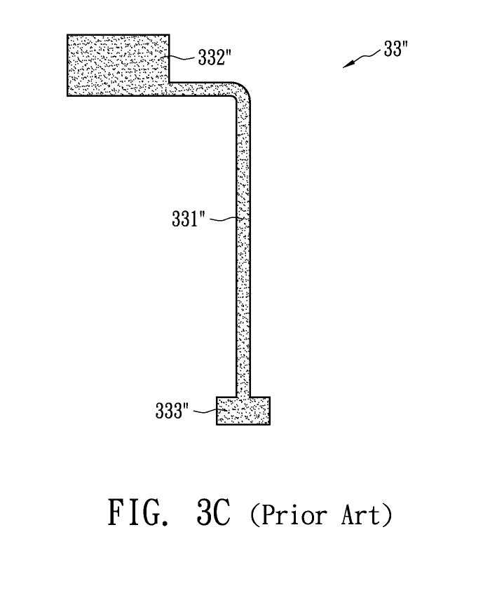

FIG. 3A is a schematic diagram of another leading wire 33 in accordance with the present invention. The two ends of the leading wire 331 are respectively connected to the terminal 332 and the contact 333, and the leading wire 331 surrounds the contact 333. As shown in FIG. 3A, the leading wire 331 approximately surrounds the contact 333 in an entire circuit, and has a rectangular ring-like route. The leading wire 331 can have various encirclement routes such as a rectangular ring, a circle ring, an octangle ring, and an irregular ring. The common mode impedance of the common mode filter can be adjusted by modifying the layout.

FIG. 3B is a schematic diagram of another leading wire 33′ in accordance with the present invention. The two ends of the leading wire 331′ are respectively connected to the terminal 332′ and the contact 333′, and the lead 331′ surrounds the contact 333′. As shown in FIG. 3B, the leading wire 331′ approximately surrounds the contact 333′ in a three fourths of full surrounding circuit route. Alternatively, there are various layouts such as one half circuit route, one fourth circuit route, multiple circuit routes, or a fractional circuit route.

FIG. 3C is a schematic diagram of a leading wire 33″ in accordance with a prior art. The two ends of the leading wire 331″ are respectively connected to the terminal 332″ and the contact 333″, and the leading wire 331″ is extended from the contact 333″ without any encirclement.

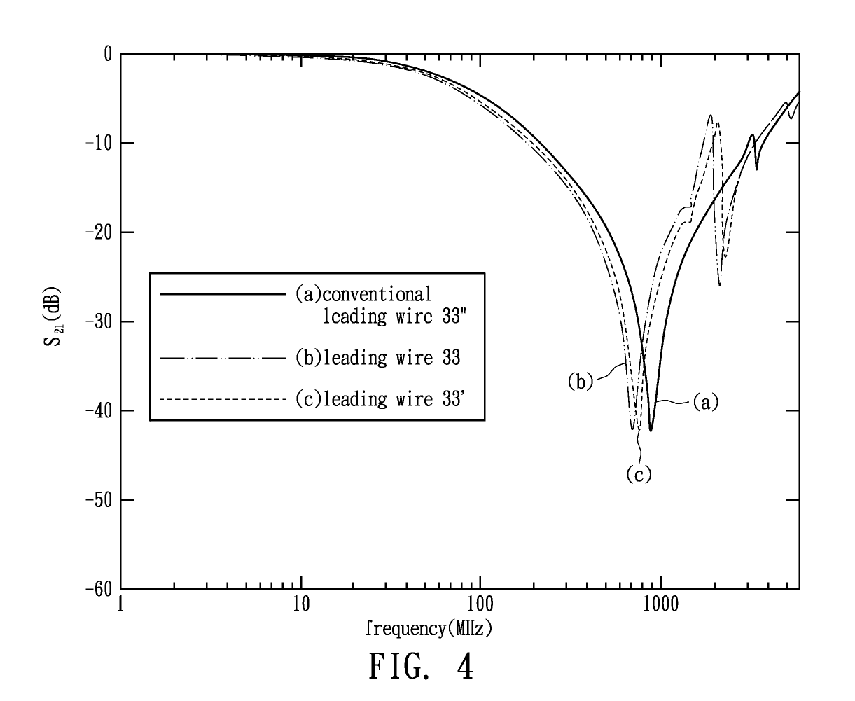

FIG. 4 is a common-mode insertion loss (S21) diagram of two leading wires in FIGS. 3A and 3B in comparison with the conventional leading wire. The conventional leading wire is extended from the contact without any encirclement, and can be compared to the example of the leading wires 33″. The diagram shows that two leading wires 33 and 33′ respectively in FIGS. 3A and 3B have higher common mode impedance so the common mode resonance frequency is accordingly reduced. Consequently, the frequency and the range of common-mode filtered frequency of the common mode filter are upgraded and adjustable.

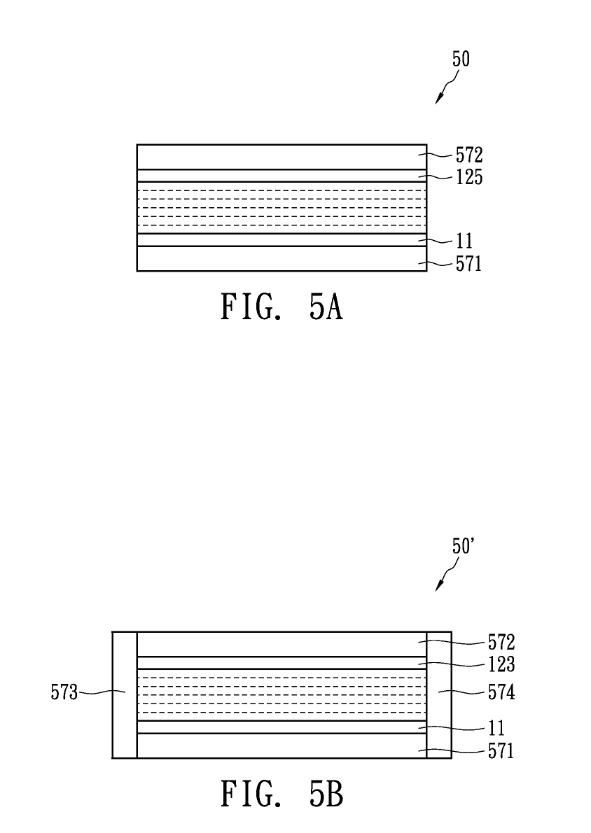

In FIGS. 1 and 2, the magnetic material layer is an upmost layer. However, it also can be a lowest layer. FIG. 5A is a schematic cross-sectional diagram of a common mode filter 50 in accordance with another embodiment of the present invention. A first magnetic material layer 571 covers the lower surface of the insulating substrate 11, and a second magnetic material layer 572 covers the upper surface of the insulating substrate 11. FIG. 5B is a schematic cross-sectional diagram of a common mode filter 50′ in accordance with another embodiment of the present invention. A third magnetic material layer 573 and a fourth material layer 574 respectively cover two laterals of the common mode filter 50′. Electrodes are disposed on the other two laterals which are not covered with a magnetic material layer. The forgoing magnetic material layer can effectively increase the inductance effects.

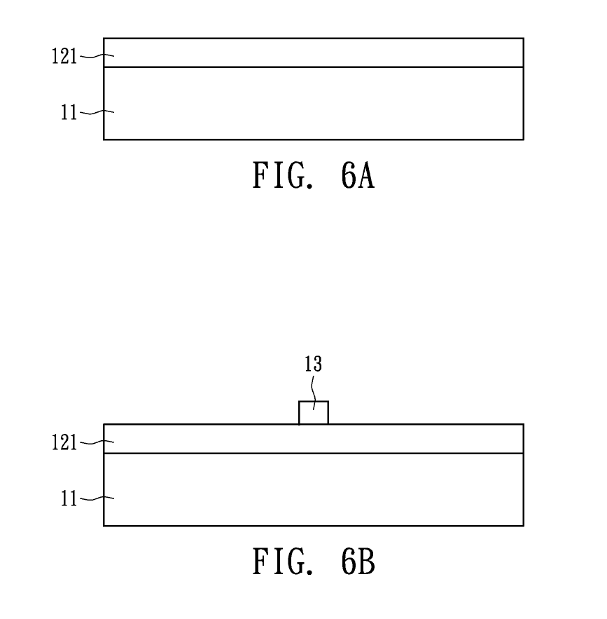

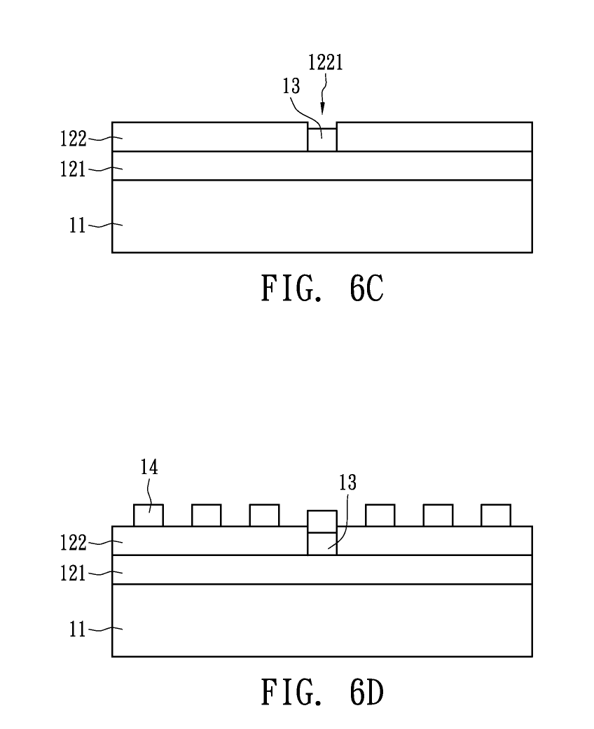

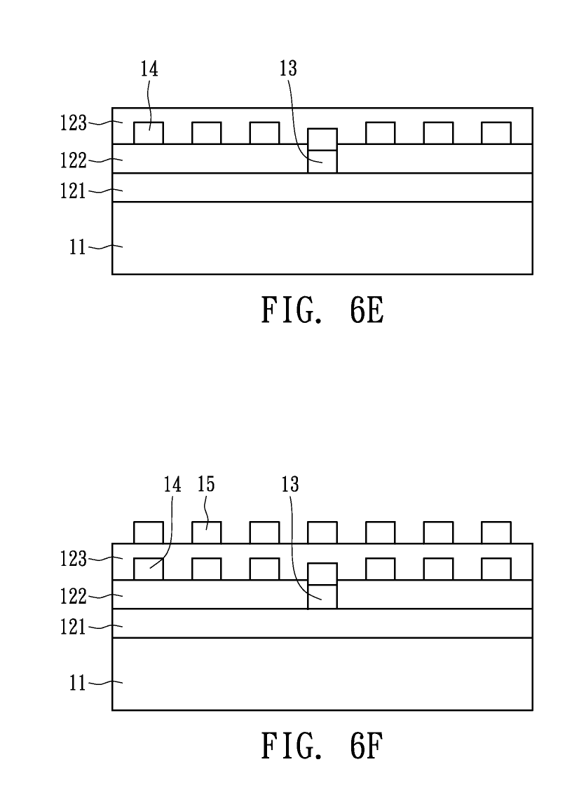

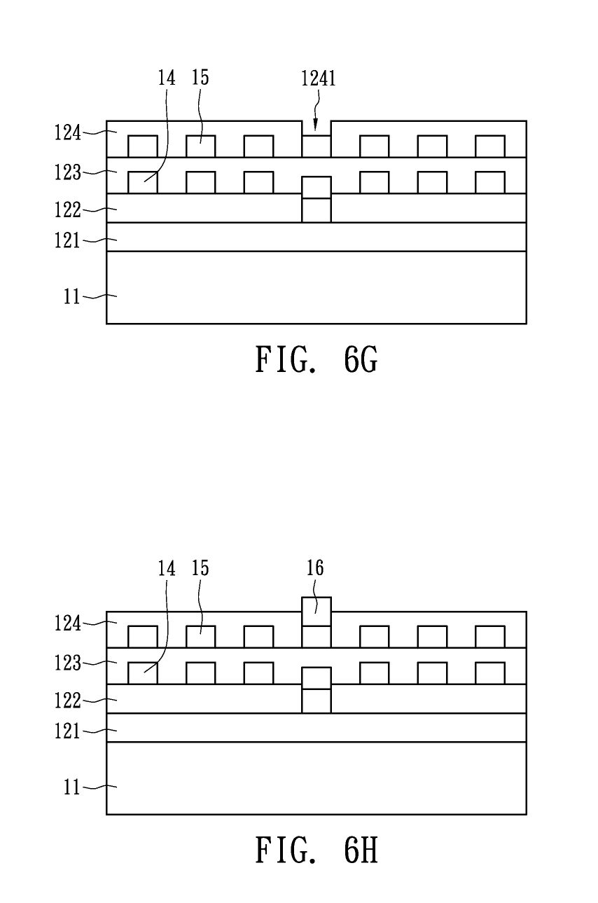

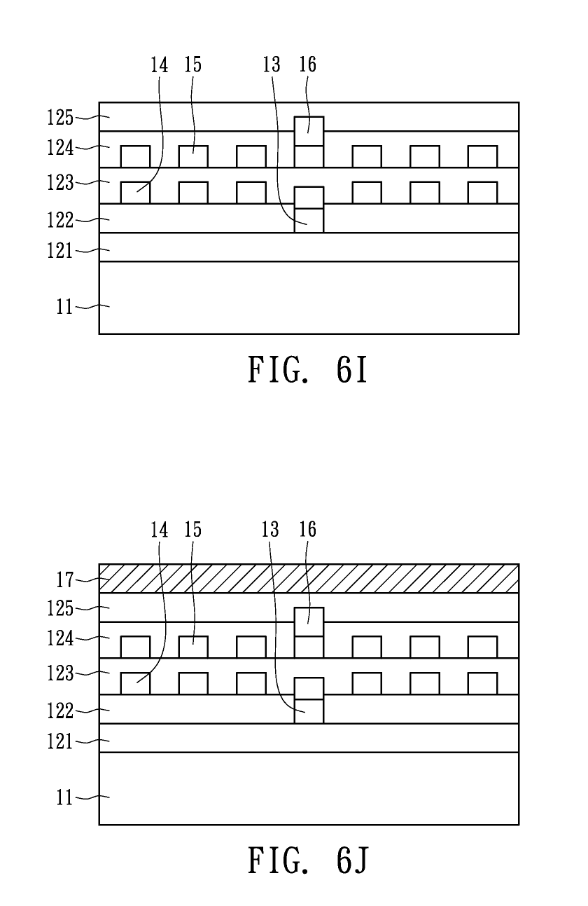

FIGS. 6A to 6J illustrate each step of a manufacturing method in accordance with an embodiment of the present invention. The first insulating layer 121 covers the insulating substrate 11 by spin coating, as shown in FIG. 6A. The lower coil leading layer 13 is made by a thin-film metal deposition process, a photolithography process, or an electroplating process. The holes 1221 are formed for the connection of the leads, as shown in FIG. 6B. Thereafter, the second insulating 122 is coated by spinning, and holes 1221 for the connections of the leads are formed thereon by a photolithography process or an etching process, as shown in FIG. 6C. The first coil main body layer 14 is formed on the second insulating layer 122 by a thin-film metal deposition process, a photolithography process, or an electroplating process, as shown in FIG. 6D. The third insulating layer 123 is coated thereon, as shown in FIG. 6E. The second coil main body layer 15 is formed on the third insulating layer 123 by a thin-film metal deposition process, a photolithography process, or an electroplating process, as shown in FIG. 6F. The fourth insulating layer 124 is coated by spinning, and holes 1241 for the connections of the leads are formed thereon by a photolithography process or an etching process, as shown in FIG. 6G. The upper coil leading layer 16 is made by a thin-film metal deposition process, a photolithography process, or an electroplating process, as shown in FIG. 6H. The fifth insulating layer 125 is coated on the upper coil leading layer 16 by spinning, as shown in FIG. 6I. The magnetic material layer 17 is formed on the fifth insulating layer 125 by an adhesion process, a screen printing process, and a spin coating process, as shown in FIG. 6J.

In view of the descriptions of the aforesaid embodiments, the present invention includes many amendments and variations to these embodiments. Therefore, it is necessary to further refer to the scope of the following claims. In addition to the aforesaid detailed descriptions, the present invention can be widely applied to various other embodiments. The above-described embodiments of the present invention are intended to be illustrative only. Those skilled in the art may devise numerous alternative embodiments without departing from the scope of the following claims.

What is claimed is:

1. A common mode filter, comprising:
an insulating substrate;
a lower coil leading layer disposed on the insulating substrate and comprising at least one lower lead, at least one lower terminal, and at least one lower contact, wherein the two ends of the lower lead are respectively connected to the lower terminal and the lower contact, and the lower lead surrounds the lower contact;
an upper coil leading layer comprising at least one upper lead, at least one upper terminal, and at least one upper contact, wherein the two ends of the upper lead are respectively connected to the upper terminal and the upper contact, and the upper lead surrounds the upper contact; and
a coil main body multilayer sandwiched between the lower coil leading layer and the upper coil leading layer.

2. The common mode filter of claim 1, wherein an encirclement route of the lower lead surrounding the low contact or an encirclement route of the upper lead surrounding the upper contact is in a shape of a square ring, a rectangular ring, a circle ring, an octangle ring or an irregular ring.

3. The common mode filter of claim 1, wherein an encirclement route of the lower lead surrounding the low contact or an encirclement route of the upper lead surrounding the upper contact has a full surrounding circuit route, one and fourth circuit route, multiple circuit routes, or a fractional circuit route.

4. The common mode filter of claim 1, further comprising a first insulating layer interposed between the insulating substrate and the lower coil leading layer.

5. The common mode filter of claim 4, wherein the coil main body multilayer comprises a second insulating layer, a first coil main body layer, a third insulating layer, a second coil main body layer, and a fourth insulating layer, and the first coil main body layer and the second coil main body layer respectively comprise at least one spiral coil.

6. The common mode filter of claim 5, further comprising a fifth insulating layer and a first magnetic material layer sequentially stacked on the upper coil leading layer.

7. The common mode filter of claim 6, further comprising a second magnetic material layer disposed on the insulating substrate.

8. The common mode filter of claim 7, further comprising a third magnetic material layer and a fourth magnetic material layer respectively disposed on two opposite laterals of the coil main body multilayer.

9. The common mode filter of claim 1, wherein the material of the insulating substrate is Al₂O₃, AlN, glass, quartz, or ferrite.

10. The common mode filter of claim 6, wherein the material of the first insulating layer, the second insulating layer, the third insulating layer, the fourth insulating layer, and the fifth insulating layer is polyimide, epoxy resin, benzocyclobutene (BCB), or polymer.

11. The common mode filter of claim 5, wherein the material of the lower coil leading layer, the first coil main body layer, the second coil main body layer, and the upper coil leading layer is Ag, Pd, Al, Cr, Ni, Ti, Au, Cu, or Pt.

12. The common mode filter of claim 8, wherein the material of the first magnetic material layer, the second magnetic material layer, the third magnetic material layer and the fourth magnetic material layer is a magnetic substrate or adhesive with magnetic powders.

13. The common mode filter of claim 12, wherein the material of the adhesive with magnetic powders is polyimide, epoxy resin, BCB or polymer mixed with magnetic powders.

14. A method for manufacturing a common mode filter, comprising the steps of:
providing an insulating substrate;
forming a lower coil leading layer on the insulating substrate, wherein the lower coil leading layer comprises at least one lower lead, at least one lower terminal, and at least one lower contact, the two ends of the lower lead are respectively connected to the lower terminal and the lower contact, and the lower lead surrounds the lower contact;
forming a coil main body multilayer on the lower coil leading layer; and
forming an upper coil leading layer on the coil main body multilayer, wherein the upper coil leading layer comprises at least one upper lead, at least one upper terminal, and at least one upper contact, the two ends of the upper lead are respectively connected to the lower terminal and the lower contact, and the upper lead surrounds the upper contact.

15. The method for manufacturing a common mode filter of claim 14, further comprising a step of coating a first insulating layer on the insulating substrate, wherein the first insulating layer is interposed between the insulating substrate and the lower coil leading layer.

16. The method for manufacturing a common mode filter of claim 15, wherein the formation of the coil main body multilayer comprises the steps of:
coating a second insulating on the lower coil leading layer and forming at least one first hole on the second insulating layer;
forming a first coil main body layer on the second insulating layer;
forming a third insulating layer on the first coil main body layer;
forming a second coil main body layer on the third insulating layer; and
coating a fourth insulating layer on the second coil main body layer and forming at least one second hole on the fourth insulating layer.

17. The method for manufacturing a common mode filter of claim 16, wherein the lower coil leading layer, the first coil main body layer, the second coil main body layer, and the upper coil leading layer are formed by a thin-film metal deposition process, a photolithography process, or an electroplating process.

18. The method for manufacturing a common mode filter of claim 16, further comprising a step of sequentially forming a fifth insulating layer and a first magnetic material layer on the upper coil leading layer.

19. The method for manufacturing a common mode filter of claim 16, wherein the first insulating layer, the second insulating layer, the third insulating layer, the fourth insulating layer, and the fifth insulating layer are formed by coating.

20. The method for manufacturing a common mode filter of claim 18, further comprising a step of forming a second magnetic material layer on a surface of the insulating substrate opposite the lower coil leading layer.

21. The method for manufacturing a common mode filter of claim 20, further comprising a step of forming a third magnetic material layer and a fourth magnetic material layer respectively on two opposite laterals of the coil main body multilayer.

22. The method for manufacturing a common mode filter of claim 14, wherein the material of the insulating substrate is Al₂O₃, AlN, glass, quartz, or ferrite.

23. The method for manufacturing a common mode filter of claim 18, wherein the material of the first insulating layer, the second insulating layer, the third insulating layer, the fourth insulating layer, and the fifth insulating layer is polyimide, epoxy resin, benzocyclobutene (BCB), or polymer.

24. The method for manufacturing a common mode filter of claim 16, wherein the material of the lower coil leading layer, the first coil main body layer, the second coil main body layer, and the upper coil leading layer is Ag, Pd, Al, Cr, Ni, Ti, Au, Cu, or Pt.

25. The method for manufacturing a common mode filter of claim 21, wherein the material of the first magnetic material layer, the second magnetic material layer, the third magnetic material layer and the fourth magnetic material layer is a magnetic substrate or adhesive with magnetic powders.

26. The method for manufacturing a common mode filter of claim 25, wherein the material of the adhesive with magnetic powders is polyimide, epoxy resin, BCB or polymer mixed with magnetic powders.
